(19) United States
(12) Patent Application Publication
(10) Pub. No.: US 2026/0198358 A1
(43) Pub. Date: Jul. 9, 2026

(54) CONNECTION SYSTEM AND METHOD FOR AN OPTIMIZED JOINING PROCESS OF BUSBARS

(71) Applicant: AUDI AG, Ingolstadt (DE)

(72) Inventors: Paul BÖCKENHOFF, Hepberg (DE); Philipp EBERHART, Ingolstadt (DE); Benjamin SÖHNLE, Ingolstadt (DE)

(73) Assignee: AUDI AG, Ingolstadt (DE)

(21) Appl. No.: 19/557,402

(22) Filed: Mar. 5, 2026

Related U.S. Application Data
(62) Division of application No. 17/496,074, filed on Oct. 7, 2021, now abandoned.

(30) Foreign Application Priority Data
Nov. 23, 2020 (DE) 102020130857.4

(51) Int. Cl. H10W 72/00; H01R 4/02; H01R 43/02; H10W 70/04

(52) U.S. Cl. CPC H10W 72/00; H01R 4/02; H01R 43/02; H10W 70/048; H10W 72/07232

(57) ABSTRACT

A method for joining two electronic circuits with the aid a connection system includes the steps of a) mechanically processing a busbar of a first electronic circuit producing a bending point in the busbar, b) arranging the at least one mechanically processed busbar of the first electronic circuit to overlap with a busbar of a second electronic circuit, c) applying a uniformly distributed joining force to the busbars arranged to be overlapping one another, both in the region of the first electronic circuit and in the region of the second electronic circuit, d) pressing down on the busbars in the region of the bending point, e) deforming at least the busbar of the first electronic circuit in the region of the bending point, and f) producing a firm connection between the busbars of the at least two circuits.

### CROSS-REFERENCE TO RELATED APPLICATION

The present application is a divisional of U.S. patent application Ser. No. 17/496,074, filed on Oct. 7, 2021, and claims the benefit of priority from German Patent Application No. 102020130857.4, filed with German Patent Office on Nov. 23, 2020. The above applications are hereby incorporated by reference in their entireties.

### FIELD

The present invention relates to a connection system and a method for optimizing a joining process.

### BACKGROUND

In the prior art, using power modules, in particular half-bridge modules or three-phase modules, in so-called hard-switching inverters is known. These are generally connected directly to an intermediate circuit capacitor via busbars. These busbars are joined together using a tool in two steps so that they can be welded. In a first step, a uniformly distributed joining force is applied to the busbars and, in a second step, a firm connection is established between the busbars of the electronic circuits, in particular the power module and the intermediate circuit capacitor, by pressing down the terminals of the power module.

However, due to the uncontrolled bending of the busbars during a joining process, stresses occur in a potting of the intermediate circuit capacitor and on a molding compound of the power module. These stresses in the material can results in the formation of cracks, which results in the material flaking off and thus a direct failure of the electronic circuits. It is also possible for moisture to penetrate due to the formation of cracks over the entire service life of the inverter, which can also results in damage and failure.

### SUMMARY

It is therefore the object of the present invention to provide a connection system and a method which improves a joining process for busbars.

This object is achieved by a connection system and by a method.

The subject matter of the present invention is a connection system comprising at least one busbar of a first electronic circuit and at least one busbar of a second electronic circuit.

According to the invention, the at least two electronic circuits represent individual components, wherein the individual components are each connectable to one another via the at least one busbar, wherein at least one of the at least one busbar of the first electronic circuit is mechanically processed.

The connection system offers the advantage that the at least one busbar can be bent at a predetermined position. As a result, a required joining force is reduced and the stresses occurring in the electronic circuits are greatly reduced.

In one embodiment, at least one of the at least one busbar is mechanically processed in such a way that it forms a predefined intended bending point. An intended bending point is a region in the material of the at least one busbar which is configured in such a way that it is bendable at a lower joining force than a material surrounding this region. An intended bending point thus offers a load minimization for a geometry of the at least one busbar. The connection system having at least one busbar formed in this way enables an optimized joining process.

In general, an intended bending point is configured as a reduction of a cross section of at least one of the at least one busbar of the first electronic circuit at a defined point. A precise specification of a bending point of the at least one busbar is possible due to this reduction.

In one refinement, at least a first of the at least two circuits is a semiconductor power module and a second of the at least two circuits is a capacitor, in particular an intermediate circuit capacitor. The invention thus relates in one embodiment, for example, to semiconductor power modules and intermediate circuit modules or intermediate circuit capacitors in the vehicle. The so-called commutation cell of an inverter represents a combination of the two components, the power module and the intermediate circuit capacitor. An inverter supplies an electric machine in a hybrid and electric vehicle with power. In principle, however, the present invention can also be applied to all power-electronic circuits/connection technologies. In a further embodiment, the at least two circuits are arbitrary or further components which are connected to one another by busbars which are welded.

In a further development, the intended bending point is formed as a minimization of a material thickness of the busbar or as an at least partially applied passage. A minimization of a material thickness is a regional reduction of a diameter of the busbar.

In a further refinement, the intended bending point is formed from a combination of a minimization of a material thickness of the busbar and a passage. In one embodiment, the intended bending point has both a reduction of a material thickness of the busbar and an at least partially applied passage.

In one embodiment, the minimization or the passage is formed as an incision, hole, notch, recess, or material removal. In one embodiment of the passage as an incision, the incision is formed, for example, up to a center of a width of the busbar. In an alternative embodiment, the incision is formed up to a quarter of a width of the busbar or up to three quarters of the width of the busbar. In an embodiment of the intended bending point as an at least partially applied passage, the busbar has a plurality of rectangular, round, or oval passages or recesses along the provided intended bending point. If the minimization is embodied as a notch, a minimization of a material thickness of the busbar based on a removal of the material is possible.

In one embodiment, the intended bending point is formed from a combination of transverse and longitudinal material removal. Due to the introduction of a joining force onto the intended bending point of the at least one busbar, the busbar bends at the point determined by the mechanical processing.

In one embodiment, the intended bending point is configured to provide a homogeneous stress of a molding compound of the first circuit and/or a potting compound of the second circuit. This offers the advantage that a deliberate avoidance of failure of material of the first and/or the second circuit can be provided. The intended bending point is thus configured to provide a homogeneous mold stress of the critical points and thus a deliberate avoidance of failure of material. A mold stress is a tension stress during a joining process in the potting of the second electronic circuit or on a molding compound, in particular a plastic molding compound, of the first electronic circuit. In particular, longitudinal and transverse weakening of the material is achievable by a combination of transverse and longitudinal material removal, due to which a homogeneous stress of the molding compound of the first circuit and/or the potting compound of the second circuit and thus a deliberate avoidance of material failures is achievable.

Furthermore, the present relates to invention, a method for joining two electronic circuits with the aid of an above-described connection system. A first electronic circuit can be a power module and a second electronic circuit can be an intermediate circuit capacitor.

In this case, in a first step a) at least one busbar of a first electronic circuit is mechanically processed in such a way that an intended bending point is produced in the at least one busbar of the first electronic circuit. Due to the introduction of mechanical processing of the at least one busbar, it is configured to bend upon an application of a joining force at a point determined by the mechanical processing, the intended bending point.

In a further step b), the at least one mechanically processed busbar of the first electronic circuit is arranged to be overlapping at least one busbar of a second electronic circuit. The at least one busbar of the second circuit is generally arranged above the at least one busbar of the first circuit.

In a further step c), a uniformly distributed joining force is applied to the busbars arranged to be overlapping one another, both in the region of the first electronic circuit and in the region of the second electronic circuit. The uniformly distributed joining force is thus applied simultaneously in at least two regions of the busbars.

In a further step d), a joining force is used to press down on the busbars in the region of the produced intended bending point. Thus, in particular, the intended bending point of the at least one busbar of the first electronic circuit, which is in particular a power module, is pressed down using a joining force.

In a further step e), at least the at least one busbar of the first electronic circuit, but in particular both busbars arranged to be overlapping one another, is deformed in the region of the intended bending point. Due to the mechanical processing, in particular the at least one busbar of the first electronic circuit is configured to deform in accordance with a shape predefined by the mechanical processing. Step e) can take place at the same time as step d).

In a further step f), a firm connection is established between the busbars of the at least two circuits. Step f) can take place at the same time as step e).

The method offers the advantage of a simpler and less expensive manufacturing or assembly method, without the formation of cracks and delamination, which is typically to be feared, between at least one of the at least one busbar and a plastic molding compound.

In one refinement of the method, the connection between the busbars is welded.

### BRIEF DESCRIPTION OF THE FIGURES

The invention is schematically illustrated in the drawings with the aid of embodiments and is described in more detail below with reference to the drawings, wherein the same components are identified by the same reference signs. In the figures:

FIG. 1 shows a side view of an embodiment of a connection system according to the invention,

FIG. 2 shows a further side view of the connection system - shown in FIG. 1,

FIG. 3a shows a sectional view of an embodiment of the connection system according to the invention with an illustration of occurring tensions,

FIG. 3b shows a further sectional view of an embodiment of the connection system according to the invention with an illustration of occurring tensions,

FIG. 4a shows a sectional view of an embodiment of the connection system according to the invention having an implementation variant of an intended bending point,

FIG. 4b shows a further sectional view of an embodiment of the connection system according to the invention having a further implementation variant of an intended bending point,

FIG. 4c shows a further sectional view of an embodiment of the connection system according to the invention having a further implementation variant of an intended bending point,

FIG. 4d shows a further sectional view of an embodiment of the connection system according to the invention having a further implementation variant of an intended bending point,

FIG. 5 shows a further sectional view of an embodiment of the connection system according to the invention having a further implementation variant of an intended bending point having a transverse and longitudinal material removal.

### DETAILED DESCRIPTION

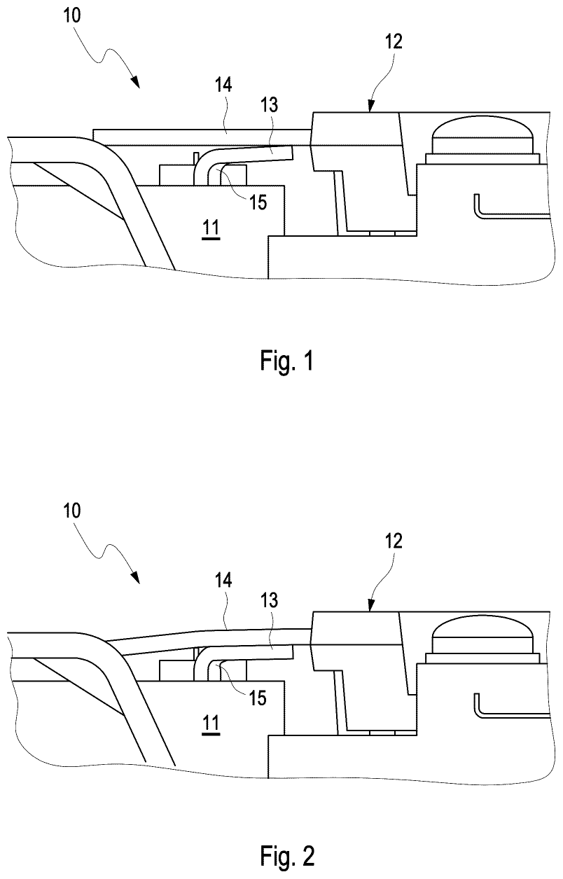

FIG. 1 shows a side view of an embodiment of a connection system 10 according to the invention. Two electronic circuits 11, 12 are shown, each of which has a busbar 13, 14. The two electronic circuits 11, 12 are arranged with respect to one another in such a way that the two busbars 13, 14 overlap. The busbar 14 of the second electronic circuit 12 rests on the busbar 13 of the first circuit 11. The busbar 13 of the first circuit 11 is formed curved.

The busbar 13 has an intended bending point 15 which was formed by the introduction of mechanical processing onto the busbar 13. At least a minimization of a material thickness of the busbar 13 or a passage in the material of the busbar 13 is achieved by the mechanical processing and the intended bending point 15 is thus defined.

In addition, FIG. 1 shows a method for joining the two electronic circuits 11, 12 having the two busbars 13, 14, wherein in a first step a uniformly distributed joining force is applied to the two busbars 13, 14. In this case, a joining force is applied to the two busbars 13, 14 in each case in the region of the first circuit 11 and in the region of the second circuit 12. In the present embodiment, the first electronic circuit 11 is a power module and the second electronic circuit 12 is an intermediate circuit capacitor.

FIG. 2 shows a further side view of the connection system 10—shown in FIG. 1. The electronic circuits 11, 12 and the busbars 13, 14 are shown, wherein the busbars 13, 14 are pressed against one another by a uniformly applied joining force.

FIG. 2 shows a further step of the method for joining the two electronic circuits 11, 12 having the two busbars 13, 14, wherein in the further step the busbars 13, 14 are pressed down with a joining force in the region of the first circuit 11 of the two circuits 11, 12.

In the process, the busbars 13, 14 are deformed in the region of the first of the two circuits 11. Both the first busbar 13 and the second busbar 14 are deformed here. The first busbar 13 is deformed in particular along the intended bending point 15. The first busbar 13 buckles along the intended bending point 15 due to the mechanical processing at the points predetermined by the mechanical processing.

A firm connection is established between the busbars 13, 14 of the two circuits 11, 12 and thus a firm connection is established between the power module and the intermediate circuit capacitor.

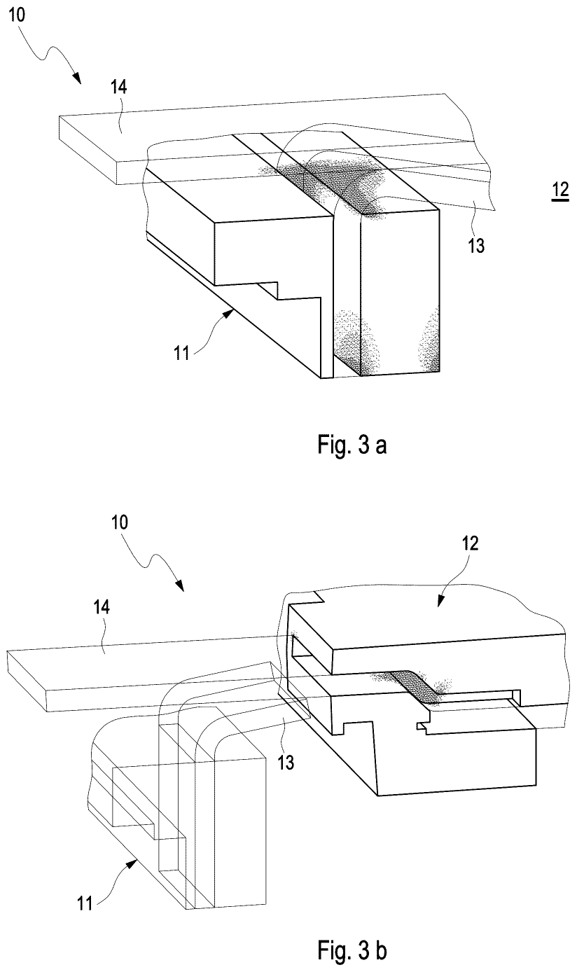

FIG. 3a shows a sectional illustration of an embodiment of the connection system 10 according to the invention with an illustration of tensions occurring in a capacitor. In particular, a tension development in the connection region of the busbars 13, 14 is shown. Only one half of a busbar 13, 14 is shown here.

In this case, voltages occur in a molding compound of the first circuit 11, in the present case the capacitor. This tension in the material can result in the formation of cracks, which can result in the material flaking off and thus a direct selection of the power module. It is also possible for moisture to penetrate due to the formation of cracks over the entire service life, which can also result in damage and failure.

FIG. 3b shows a further sectional view of an embodiment of the connection system 10 according to the invention with an illustration of occurring tensions in a power module. A tension development in the connection region of the busbars 13, 14 is shown. Only one half of a busbar 13, 14 is shown here.

In this case, tensions occur in a potting compound of the second circuit 12, the power module.

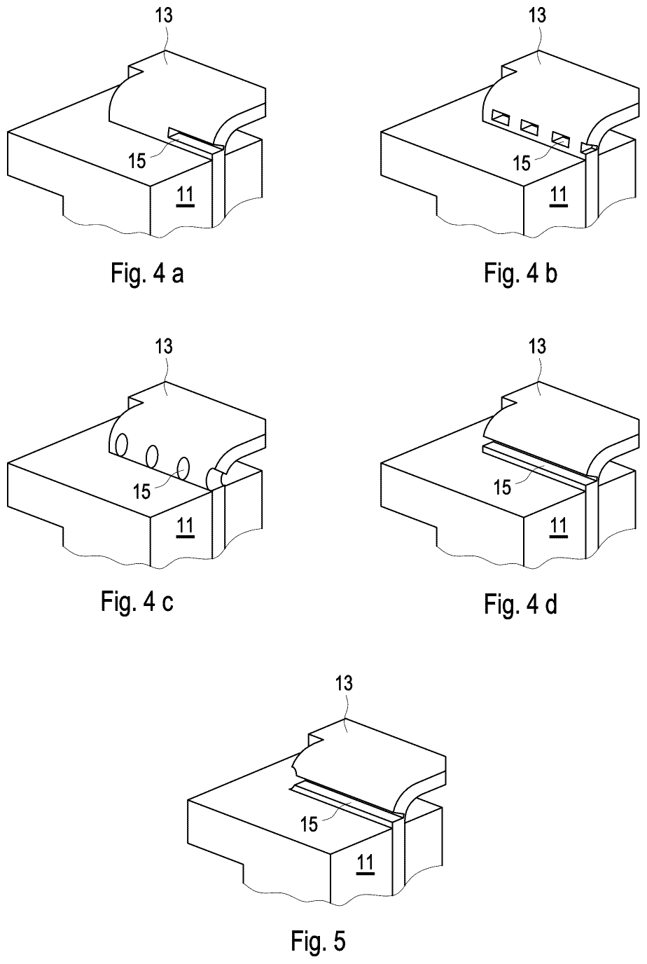

FIG. 4a shows a sectional view of an embodiment of the connection system 10 according to the invention having an implementation variant of an intended bending point 15. The intended bending point 15 is formed as an incision in the present embodiment. In the present embodiment, the incision extends up to a center of a width of the busbar. In alternative embodiments, the incision extends at least up to a quarter of a width of the busbar or three quarters of a width of the busbar.

FIG. 4b shows a further sectional view of an embodiment of the connection system 10 according to the invention having a further implementation variant of an intended bending point 15. The intended bending point 15 is formed in the present embodiment from a plurality of rectangular holes or recesses.

FIG. 4c shows a further sectional view of an embodiment of the connection system 10 according to the invention having a further implementation variant of an intended bending point 15. The intended bending point 15 is formed in the present embodiment from a plurality of round or oval holes or recesses.

FIG. 4d shows a further sectional view of an embodiment of the connection system 10 according to the invention having an implementation variant of an intended bending point 15. The intended bending point 15 is formed as a notch in the present embodiment. The notch extends over the entire width of the busbar.

FIG. 5 shows a further sectional view of an embodiment of the connection system 10 according to the invention having a further implementation variant of an intended bending point 15 made up of a transverse and longitudinal material removal.

### LIST OF REFERENCE SIGNS

10 connection system
11 first electronic circuit
12 second electronic circuit
13 at least one busbar of the first electronic circuit
14 at least one busbar of the second electronic circuit
15 intended bending point

1. A method for joining two electronic circuits, comprising the following steps
a) mechanically processing at least one busbar of a first electronic circuit and thus producing an intended bending point in the at least one busbar of the first electronic circuit,
b) arranging the at least one mechanically processed busbar of the first electronic circuit to be overlapping with at least one busbar of a second electronic circuit,
c) applying a uniformly distributed joining force to the busbars arranged to be overlapping one another, both in the region of the first electronic circuit and in the region of the second electronic circuit,
d) pressing down with a joining force on the busbars in the region of the produced intended bending point,
e) deforming at least the at least one busbar of the first electronic circuit, but in particular the busbars arranged to be overlapping one another, in the region of the intended bending point,
f) producing a firm connection between the busbars of the at least two circuits.

2. The method as claimed in claim 1, wherein the connection between the busbars is welded.
